(19) United States
(12) Patent Application Publication
(10) Pub. No.: US 2012/0158345 A1
(43) Pub. Date: Jun. 21, 2012

(54) CURRENT BALANCE TESTING SYSTEM

(75) Inventors: DAN-DAN LIU, Shenzhen City (CN); BO DENG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/071,521

(22) Filed: Mar. 25, 2011

(30) Foreign Application Priority Data
Dec. 16, 2010 (CN) 201010591343.1

(51) Int. Cl. G01R 31/00

(52) U.S. Cl. 702/117

(57) ABSTRACT

A current balance testing system is configured for measuring current flowing in a main board, the main board comprises a load, a power source supplying power to the loads, and a number of inductors connected between the power source and the loads. The current balance testing system includes a data acquiring device and a data processing device. The data acquiring device includes a plurality of input terminals and an output terminal, each input terminal correspondingly is connected to one inductor and configured for measuring a voltage drop across the inductor. The data processing device is connected to the output terminal and stores resistances of the inductors in the data processing device. The data processing device uses the voltage drops and the resistances of the inductors to calculate the current flowing through the inductors to determine whether or not the current flowing between the power source and the load are balanced.

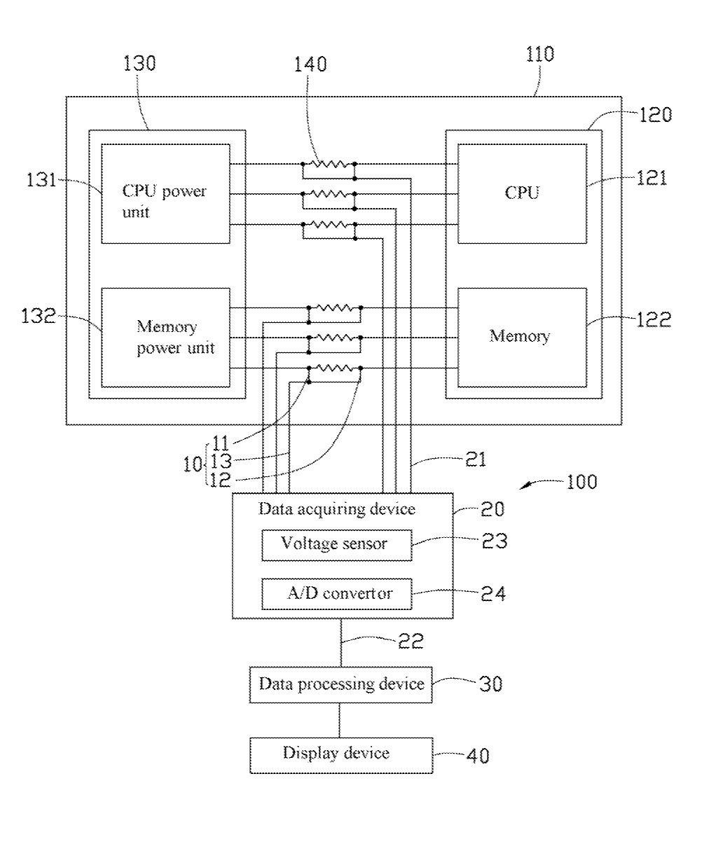

### BACKGROUND

1. Technical Field

The present disclosure relates to testing systems, and particularly, to a current balance testing system.

2. Description of Related Art

Electronic elements of a device may be powered by different power sources through different circuits. If current flowing through the circuits are unbalanced (e.g., unequal to each other), the electronic device may be damaged. Therefore, current balance testing should be carried out on electronic devices before they leave the factory. Testing may be done with the aid of an oscilloscope. However, resistance of the probes of the oscilloscope is difficult to account for and may result in inaccurate testing.

Therefore, it is desirable to provide a current balance testing system which can overcome the limitations described.

### BRIEF DESCRIPTION OF THE DRAWING

The FIGURE is a schematic view of a current balance testing system in accordance with an exemplary embodiment.

### DETAILED DESCRIPTION

Embodiments of the disclosure will now be described in detail, with reference to the accompanying drawing.

Referring to the FIGURE, a current balance testing system 100, according to an exemplary embodiment, is configured for measuring if current flowing through a main board 110 are balanced. The main board 110 includes a load 120, a power source 130, and a number of inductors 140. The power source 130 supplies power to the load 120 through a number of circuits (not labeled). The inductors 140 are included in the circuits.

In this embodiment, the load 120 includes a central processing unit (CPU) 121 and a memory 122. The power source 130 includes a CPU power unit 131 and a memory power unit 132. The CPU power unit 131 supplies power to the CPU 121 through a number of circuits. The memory power unit 132 supplies power to the memory 122 through a number of circuits. The inductors 140 filter noise from current flowing in the circuits. A part of inductors 140 are included in the circuits between the CPU power unit 131 and the central processing unit 121 respectively, while another part of inductors 140 are also included in the circuits between the memory power unit 132 and the memory 122 respectively. The types of all of the inductors 140 are the same.

The current balance testing system 100 includes a number of probes 10, a data acquiring device 20, a data processing device 30, and a display device 40.

Each of the probes 10 includes a data terminal 11, a first acquiring terminal 12, and a second acquiring terminal 13. The data terminal 11 is connected with the data acquiring device 20. The first acquiring terminal 12 and the second acquiring terminal 13 of the probe 10 are connected to two ends of the corresponding inductor 140.

The data acquiring device 20 includes a number of input terminals 21 and an output terminal 22. Each input terminal 21 is connected to the data terminal 11 of the probe 10. In this embodiment, the data acquiring device 20 includes a voltage sensor 23 and an analog-to-digital (A/D) convertor 24. The voltage sensor 23 is configured for acquiring voltage drops across the inductor 140 using a corresponding probe 10. The A/D convertor 24 is configured for converting analog signals into digital signals.

The data processing device 30 is connected to the output terminal 22 of the data acquiring device 20. Resistances of the inductors 140 are pre-stored in the data processing device 30. The data processing device 30 calculates value of the current flowing through each of the inductors 140 according to the digital signals transmitted from the data acquiring device 20 and the resistances of the inductors 140. The data processing device 30 compares the current values and determines whether or not the current flowing between the power source 130 and the load 120 are balanced.

The display device 40 is an LCD, and configured to indicate whether t or not the current flowing between the power source 130 and the load 120 are balanced. In this embodiment, the display device 40 includes two different display units. One of the display units is configured for indicating whether or not the current flowing between the CPU power unit 131 and the CPU 121 are balanced, and the other display unit is configured for indicating whether or not the current flowing between the memory power unit 132 and the memory 122 are balanced.

During testing, the data acquiring device 20 acquires a number of voltage drops of two terminals of the inductors 140 through the probe 10. The data acquiring device 20 converts the voltage drops from analog signals to digital signals. The data processing device 30 accepts the digital signals from the data acquiring device 20, and using the resistances of the inductors 140 calculates the current values. The data processing device 30 then determines the current values and determines whether or not the current are balanced. The display device 40 indicates whether or not the current flowing between the power source 130 and the load 120 are balanced according to a signal from the data processing device 30.

Particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A current balance testing system is configured for measuring current flowing through a main board; the main board comprising a load, a power source supplying power to the load, and a number of inductors connected between the power source and the load; the current balance testing system comprising:
a data acquiring device comprising a plurality of input terminals and an output terminal, each of the input terminals correspondingly connected to one inductor and configured for acquiring a voltage drop across two terminals of the inductor; and
a data processing device connected to the output terminal and storing resistances of the inductor, the data processing device using the values of the voltage drops and the resistances of the inductors to calculate the current flowing through the inductors to determine whether or not the current flowing between the power source and the load are balanced.

2. The current balance testing system of claim 1, further comprising a plurality of probes, each of the probes comprising a data terminal connected to the input terminal of the data acquiring device and a first and a second acquiring terminals connected to the two terminals of the inductor.

3. The current balance testing system of claim 1, wherein the load comprises a central processing unit and a memory, the power source comprises a CPU power unit supplying power to the central processing unit and a memory power unit supplying power to the memory.

4. The current balance testing system of claim 1, further comprising a display device, the display device is configured for indicating whether or not the current flowing between the power source and the load are balanced.

5. The current balance testing system of claim 1, wherein the data acquiring device comprises a voltage sensor configured for acquiring voltage drops across the two terminals of each of the inductors and an A/D convert configured for converting analog signals into digital signals.
